(19) United States
(12) Patent Application Publication
(10) Pub. No.: US 2018/0277426 A1
(43) Pub. Date: Sep. 27, 2018

(54) METHODS OF FORMING CONDUCTIVE STRUCTURES

(71) Applicant: GLOBALFOUNDRIES Inc., Grand Cayman (KY)

(72) Inventors: Ruilong Xie, Niskayuna, NY (US); Xunyuan Zhang, Albany, NY (US)

(21) Appl. No.: 15/467,628

(22) Filed: Mar. 23, 2017

(51) Int. Cl. H01L 21/768; H01L 21/3213; H01L 23/532; H01L 23/528

(52) U.S. Cl. CPC H01L 21/76846; H01L 21/76802; H01L 21/32134; H01L 21/32135; H01L 23/528; H01L 21/76877; H01L 23/53238; H01L 23/53266; H01L 21/7684

(57) ABSTRACT

One illustrative method disclosed herein includes, among other things, forming a first trench/via and a wider second trench/via in a layer of insulating material, forming a conductive adhesion layer in the first and second trench/vias and forming a conductive liner layer in the second trench/via such that the material of the conductive liner layer substantially fills the first trench/via. In this particular example, the method also includes removing portions of the conductive liner layer positioned within the second trench/via and above an upper surface of the conductive adhesion layer and removing portions of the conductive adhesion layer positioned above an upper surface of the layer of insulating material to define a conductive structure positioned in the first trench/via that comprises the material of the conductive adhesion layer and the material of the conductive liner layer.

### BACKGROUND OF THE INVENTION

### 1. Field of the Invention

Generally, the present disclosure relates to the manufacture of semiconductor devices, and, more specifically, to various methods of forming various conductive structures, such as conductive lines/vias, that include a conductive liner layer without performing a CMP process to remove portions of the liner layer.

### 2. Description of the Related Art

The fabrication of advanced integrated circuits, such as CPUs, storage devices, ASICs (application specific integrated circuits) and the like, requires a large number of circuit elements, such as transistors, capacitors, resistors, etc., to be formed on a given chip area according to a specified circuit layout. During the fabrication of complex integrated circuits using, for instance, MOS (Metal-Oxide-Semiconductor) technology, millions of transistors, e.g., N-channel transistors (NFETs) and/or P-channel transistors (PFETs), are formed on a substrate including a crystalline semiconductor layer. A field effect transistor, irrespective of whether an NFET transistor or a PFET transistor is considered, typically includes doped source and drain regions that are formed in a semiconducting substrate and separated by a channel region. A gate insulation layer is positioned above the channel region and a conductive gate electrode is positioned above the gate insulation layer. By applying an appropriate voltage to the gate electrode, the channel region becomes conductive and current is allowed to flow from the source region to the drain region.

To improve the operating speed of field effect transistors (FETs), and to increase the density of FETs on an integrated circuit device, device designers have greatly reduced the physical size of FETs over the past decades. More specifically, the channel length of FETs has been significantly decreased, which has resulted in improving the switching speed of FETs and the overall functionality of the circuit. Further scaling (reduction in size) of the channel length of transistors is anticipated in the future. While this ongoing and continuing decrease in the channel length of transistor devices has improved the operating speed of the transistors and integrated circuits that are formed using such transistors, there are certain problems that arise with the ongoing shrinkage of feature sizes that may at least partially offset the advantages obtained by such feature size reduction. For example, as the channel length is decreased, the pitch between adjacent transistors likewise decreases, thereby increasing the density of transistors per unit area. This scaling also limits the size, i.e., the lateral width, of at least some of the conductive contact elements and structures, such as conductive lines and vias, which has the effect of increasing their electrical resistance. In general, the reduction in feature size and increased packing density makes everything more crowded on modern integrated circuit devices. Moreover, the physical size of these conductive structures is typically not uniform across an integrated circuit product, i.e., there may be regions that have very densely packed structures with very small lateral dimensions (such as device level contacts that actually contact the transistor devices) while there may be other regions (e.g., edge seal, crackstop) with conductive structures that have, in a relative sense, much larger lateral dimensions.

Typically, due to the large number of circuit elements and the required complex layout of modern integrated circuits, the electrical connections of the individual circuit elements cannot be established within the same level on which the circuit elements, such as transistors, are manufactured. Rather, modern integrated circuit products have multiple so-called metallization layer levels that, collectively, contain the “wiring” pattern for the product, i.e., the conductive structures that provide electrical connection to the transistors and the circuits, such as conductive vias and conductive metal lines. In general, the conductive metal lines are used to provide intra-level (same level) electrical connections, while inter-level (between levels) connections or vertical connections are referred to as vias. In short, the vertically oriented conductive via structures provide the electrical connection between the various stacked metallization layers. Accordingly, the electrical resistance of such conductive structures, e.g., lines and vias, becomes a significant issue in the overall design of an integrated circuit product, since the cross-sectional area of these elements is correspondingly decreased, which may have a significant influence on the effective electrical resistance and overall performance of the final product or circuit.

Copper (Cu) and tungsten (W) are currently the most common conductive materials used in conductive interconnect structures. But, as the critical dimension of such interconnects is reduced, e.g., to 20 nm and below, it may become more difficult to manufacture conductive structures comprised of copper or tungsten. Thus, there are ongoing investigations into the use of other conductive materials, such as ruthenium (Ru), to replace copper or tungsten, in whole or part, in such small scale conductive structures.

The formation of copper and tungsten metallization structures typically involves performing several process steps. FIGS. 1A-1B depict one illustrative prior art technique for forming a conductive copper or tungsten structure. In general, the metallization technique involves: (1) forming one or more trenches/vias 12 in a layer of insulating material 14; (2) depositing one or more relatively thin barrier layers 16 (e.g., TiN, TaN); (3) forming an adhesion or wetting layer 18 on the barrier layer 16; (4) forming bulk copper or tungsten material 20 across the substrate and in the trenches/vias 12; and (5) performing one or more chemical mechanical polishing (CMP) processes to remove the excess portions of the barrier layer 16, the adhesion layer 18 and the copper or tungsten material 20 positioned outside of the trenches/vias 12 to define the illustrative final conductive copper or tungsten structures 22 depicted in FIG. 1B. As is well known to those skilled in the art, the copper material 20 is typically formed by performing an electrochemical copper deposition process after a thin conductive copper seed layer (not shown in FIG. 1A) is deposited by physical vapor deposition (PVD) on the adhesion layer 18 (e.g., tantalum, ruthenium, cobalt, etc.), while tungsten bulk material may be deposited by chemical vapor deposition (CVD) on the adhesion layer 18 (e.g., boron doped tungsten).

However, as everything becomes more crowded on an integrated circuit product, problems may arise when employing traditional metallization techniques. More specifically, it becomes more difficult to reliably fill very small trench/via patterns with copper or tungsten. To that end, semiconductor manufacturers have started to use other materials, such as ruthenium, to form such conductive structures. Ruthenium exhibits excellent (low) electrical resistance characteristics and low metal migration characteristics as the dimensions of the conductive structure is reduced (scaled). Ruthenium is a noble metal that may not be easily removed by performing a chemical mechanical polishing (CMP) process.

Additionally, ruthenium is a relatively expensive material, and, accordingly, it may not be economically viable to deposit ruthenium as the overfill material that would subsequently need to be removed by performing a CMP process.

The present disclosure is directed to various methods of forming various conductive structures that may solve or at least reduce some of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming conductive structures, such as conductive lines/vias. One illustrative method disclosed herein includes, among other things, forming a first trench/via and a wider second trench/via in a layer of insulating material, forming a conductive adhesion layer in the first trench/via and the second trench/via and performing a deposition process that results in the formation of a conductive liner layer in the second trench/via and such that the material of the conductive liner layer substantially fills the first trench/via. In this particular example, the method also includes performing an etching process to remove at least a portion of the conductive liner layer positioned within the second trench/via and above an upper surface of the conductive adhesion layer while leaving a portion of the conductive liner layer within the first trench/via, and removing portions of the conductive adhesion layer positioned above an upper surface of the layer of insulating material to define a conductive structure positioned in the first trench/via that comprises the material of the conductive adhesion layer and the material of the conductive liner layer.

Another illustrative method disclosed herein includes, among other things, forming a first trench/via and a wider second trench/via in a layer of insulating material, forming a conductive adhesion layer in the first and second trench/vias and above the upper surface of the layer of insulating material and performing a deposition process that results in the formation of a conductive liner layer in the second trench/via and such that the material of the conductive liner layer substantially fills the first trench/via. In this particular example, the method further includes performing a wet isotropic etching process to remove substantially all of the conductive liner layer positioned within the second trench/via and from above the upper surface of the layer of insulating material while leaving a portion of the conductive liner layer within the first trench/via, overfilling at least the second trench/via with a bulk conductive material and performing at least one process operation to remove portions of the bulk conductive material and the conductive adhesion layer from above the upper surface of the layer of insulating material to thereby result in the formation of a first conductive structure in the first trench/via and a second conductive structure in the second trench/via.

Yet another illustrative method disclosed herein includes, among other things, forming a first trench/via and a wider second trench/via in a layer of insulating material, forming a conductive adhesion layer in the first and second trench/vias and above the upper surface of the layer of insulating material and performing a deposition process that results in the formation of a conductive liner layer in the second trench/via and such that the material of the conductive liner layer substantially fills the first trench/via. In this particular example, the method also includes performing a dry anisotropic etching process on the conductive liner layer such that, after the dry anisotropic etching process is completed, a portion of the material of the conductive liner layer substantially fills the first trench/via and an internal sidewall spacer is defined within the second trench/via that is comprised of the material of the conductive liner layer, overfilling at least the second trench/via with a bulk conductive material and performing at least one process operation to remove portions of the bulk conductive material, the conductive adhesion layer and the conductive liner layer from above the upper surface of the layer of insulating material to thereby result in the formation of a first conductive structure in the first trench/via and a second conductive structure in the second trench/via.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1B depict an illustrative prior art metallization process for forming conductive structures;

FIGS. 2A-2E depict various novel methods disclosed herein for forming conductive structures, such as conductive lines/vias, that include a conductive liner layer without performing a CMP process to remove portions of the liner layer; and

FIGS. 3A-3D depict various other novel methods disclosed herein for forming conductive structures, such as conductive lines/vias.

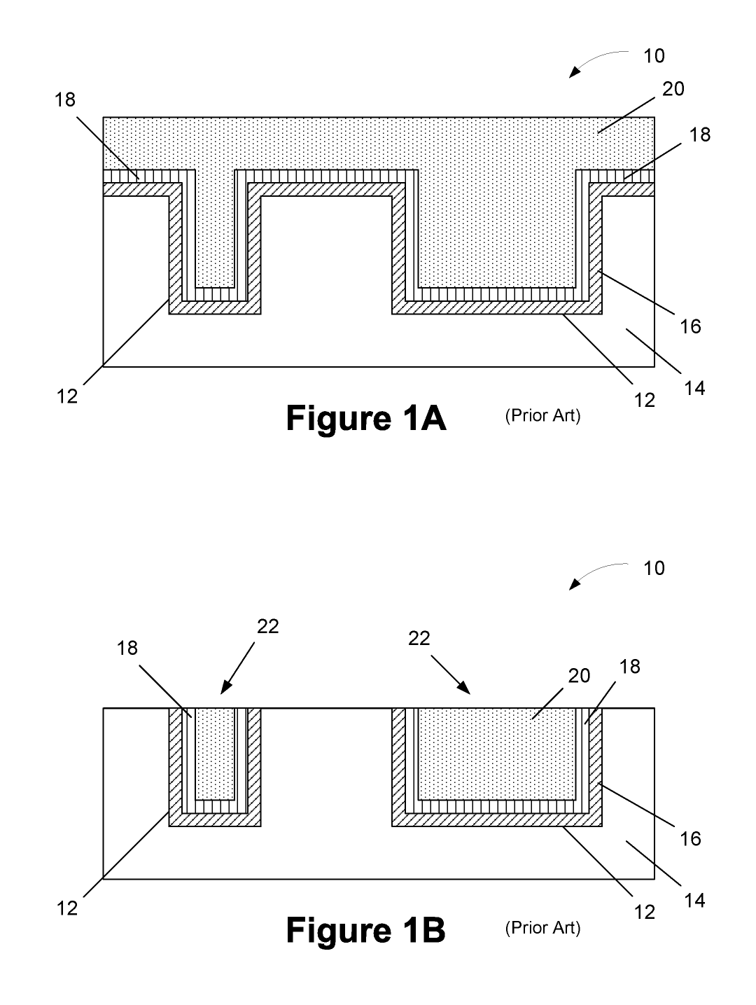

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase. To the extent the term “adjacent” is used herein and in the attached claims to described a positional relationship between two components or structures, that term should be understood and construed so as to cover situations where there is actual physical contact between the two components and to cover situations where such components are positioned near one another but there is no physical contact between the two components. Physical contact between two components will be specified within the specification and claims by use of the phrase “on and in contact with” or other similar language. As will be readily apparent to those skilled in the art upon a complete reading of the present application, the methods disclosed herein may be employed in manufacturing a variety of different devices, including, but not limited to, logic devices, memory devices, etc., and the devices may be may be either NMOS or PMOS devices.

As will be appreciated by those skilled in the art after a complete reading of the present application, various doped regions, e.g., halo implant regions, well regions and the like, are not depicted in the attached drawings. Of course, the inventions disclosed herein should not be considered to be limited to the illustrative examples depicted and described herein. The various components and structures of the device 100 disclosed herein may be formed using a variety of different materials and by performing a variety of known techniques, e.g., a chemical vapor deposition (CVD) process, an atomic layer deposition (ALD) process, a thermal growth process, spin-coating techniques, etc. The thicknesses of these various layers of material may also vary depending upon the particular application. With reference to the attached figures, various illustrative embodiments of the methods and devices disclosed herein will now be described in more detail.

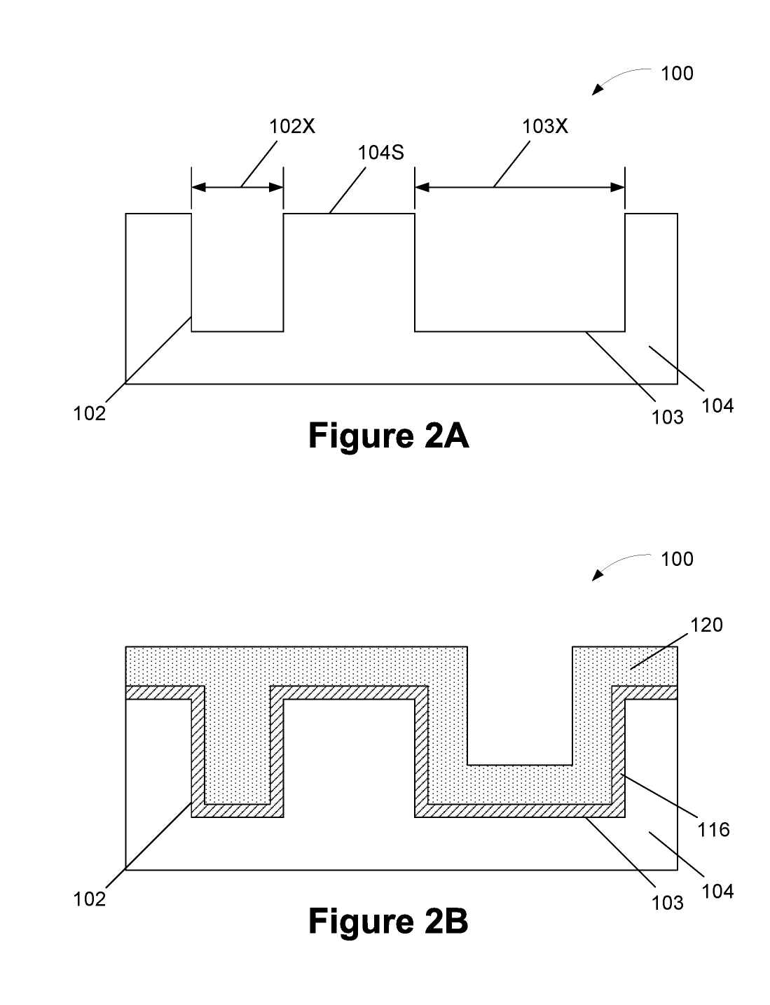

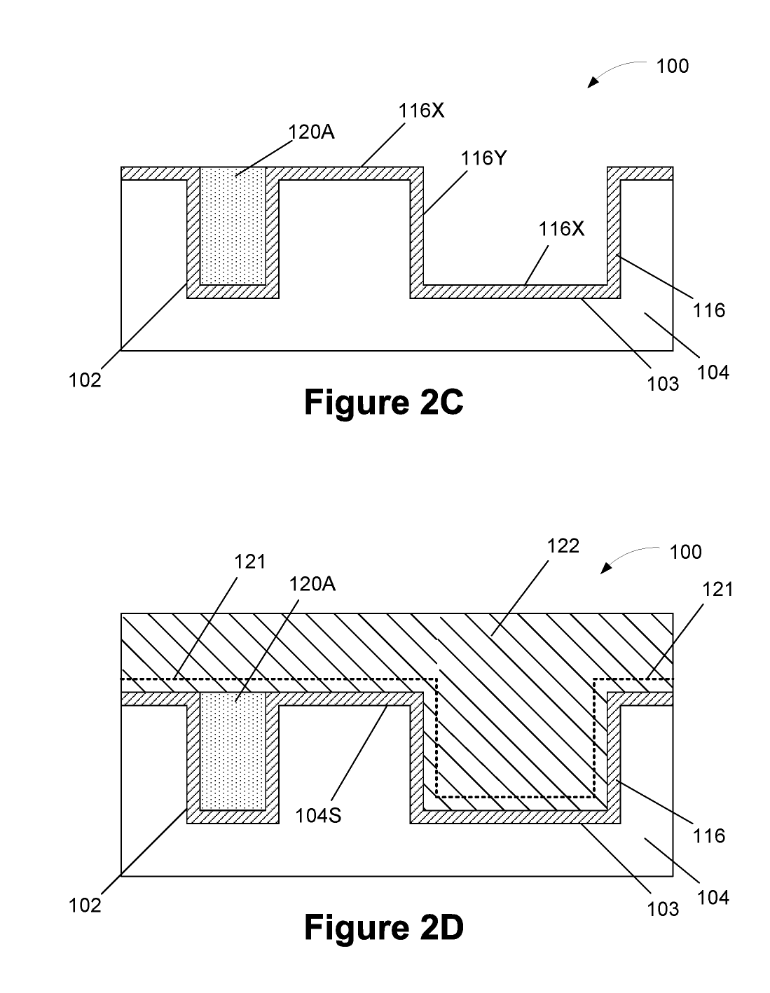

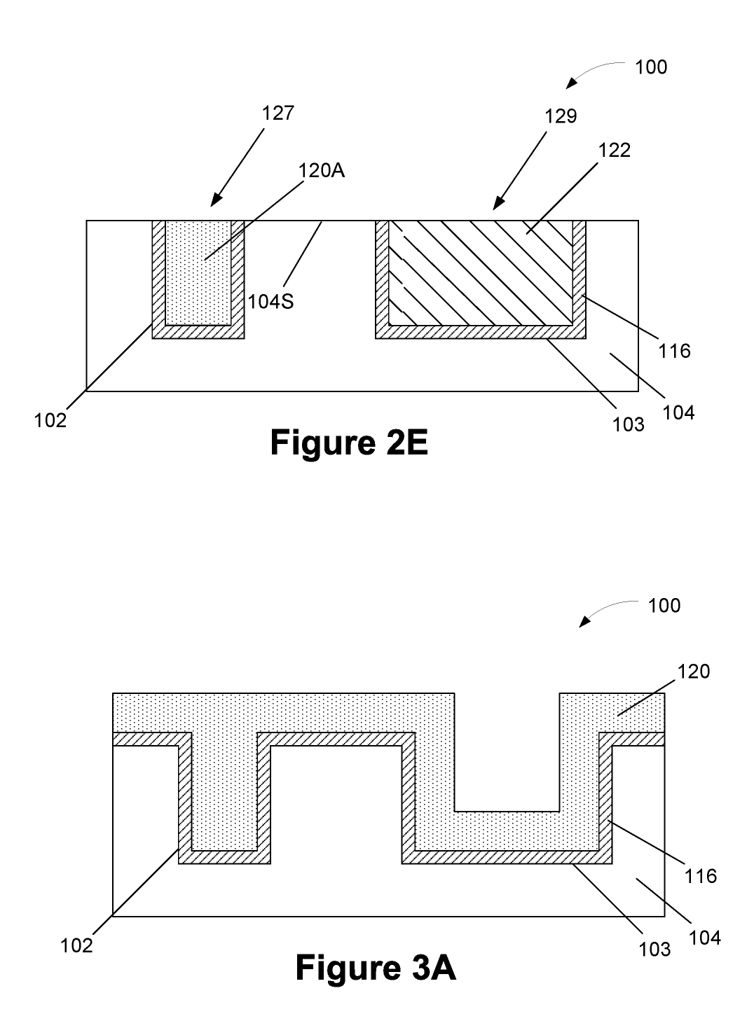

FIGS. 2A-2E depict various novel methods disclosed herein for forming conductive structures, such as conductive lines/vias, that include a conductive liner layer without performing a CMP process to remove portions of the liner layer. FIG. 2A is a simplified view of an illustrative integrated circuit product or device 100 at an early stage of manufacturing that is formed above a semiconductor substrate (not shown). The substrate may have a variety of configurations, such as a bulk substrate configuration, an SOI (silicon-on-insulator) configuration, and it may be made of materials other than silicon. Thus, the terms “substrate” or “semiconductor substrate” should be understood to cover all semiconducting materials and all forms of such materials. The device 100 may be any type of integrated circuit device that employs any type of a conductive structure, such as a conductive line or via, commonly found on integrated circuit devices.

FIG. 2A depicts the product 100 after a first trench/via 102 and a second trench/via 103 was formed in a layer of insulating material 104 by performing known photolithography and etching techniques through a patterned mask layer (not shown). The trench/vias 102/103 are intended to be representative of any type of opening formed in any type of insulating material 104 wherein a conductive copper structure may be formed. The trench/vias 102/103 may be of any desired shape, depth or configuration and they may have different configurations or be of a different size. For example, the first trench/via 102 may have a lateral width 102X (as measured at the upper surface 104S of the layer of insulating material 104) that is smallest on the product for such conductive structures, i.e., a so called “ground rule line,” while the second trench/via 103 may have a much larger lateral width 103X. By way of example only, in current-day devices, the width 102X may be on the order of about 10-60 nm, while the width 103X (as measured at the upper surface 104S of the layer of insulating material 104) may be on the order of about 100 nm or larger. In one particular example, the width 103X may be at least 10 nm larger than the width 102X. In some embodiments, one or both of the trench/vias 102/103 may be a classic trench that does not extend through to an underlying layer of material, such as the illustrative trench/vias 102/103 depicted in FIG. 2A. In other embodiments, one or both of the trench/vias 102/103 may be a through-hole type feature, e.g., a classic via, that extends all of the way through the layer of insulating material 104 and exposes an underlying layer of material or an underlying conductive structure (not shown), such as an underlying metal line. Thus, the shape, size, depth or configuration of the trench/vias 102/103 should not be considered to be a limitation of the present inventions. The trench/vias 102/103 may be formed by performing any of a variety of different etching processes, e.g., a dry reactive ion etching process, through the patterned mask layer (not shown).

The various components and structures of the device 100 may be initially formed using a variety of different materials and by performing a variety of known techniques. For example, the layer of insulating material 104 may be comprised of any type of insulating material, e.g., a low-k insulating material (k value less than 3.3), etc., it may be formed to any desired thickness and it may be formed by performing, for example, a chemical vapor deposition (CVD) process or spin-on deposition (SOD) process, etc.

FIG. 2B depicts the product 100 after several process operations were performed. First, a deposition process, e.g., a CVD, an atomic layer deposition (ALD) process or physical vapor deposition (PVD) process, was performed to form a conductive adhesion layer 116 across the product 100 and in the trench/vias 102/103. The conductive adhesion layer 116 may be a metal-containing material, e.g., a metal, a pure metal, a metal alloy, a metal nitride, a metal oxide, etc. In one illustrative example, the conductive adhesion layer 116 may be comprised of titanium nitride. The thickness of the conductive adhesion layer 116 may vary depending upon the particular application, e.g., 0.5-3 nm. Next, a deposition process, e.g., an ALD or CVD process, was performed to form a conductive liner layer 120 on the conductive adhesion layer 116. In one illustrative example, the conductive liner layer 120 may be comprised of a noble metal, e.g., ruthenium, etc. The thickness of the conductive liner layer 120 may vary depending upon the particular application, e.g., 5-40 nm, but it should be formed to a sufficient thickness such that it “pinches-off” so as to fill the smaller first trench/via 102 while leaving a portion of the larger second trench/via 103 unfilled.

FIG. 2C depicts the product 100 after a timed, wet isotropic etching process was performed to selectively remove the conductive liner layer 120 relative to the conductive adhesion layer 116. Note that the wet isotropic etching process is performed such that the conductive liner layer 120 is removed from the wider second trench/via 103 while a portion 120A of the conductive liner layer 120 remains in the smaller first trench/via 102. Also note that the conductive liner layer 120 is removed from above the substantially horizontally oriented surfaces 116X of the conductive adhesion layer 116 and the substantially vertically oriented surfaces 116Y of the conductive adhesion layer 116.

FIG. 2D depicts the product 100 after several process operations were performed. In general, one or more conductive materials will be formed above the device to complete the formation of a conductive structure in the second trench/via 103. For example, in one embodiment, a PVD process was performed to form a copper-based seed layer 121 (shown as a dashed line) above the conductive liner layer portion 120A and the conductive adhesion layer 116. Thereafter, a bulk deposition process was performed to form bulk copper material 122 across the product 100 such that it overfills the second trench/via 103. The bulk copper 122 may be formed by performing any of a variety of known electroplating or electroless deposition processes. Of course, the conductive materials formed on the product at the point of processing depicted in FIG. 2C may vary depending upon the particular application. For example, tungsten could be employed in lieu of copper.

FIG. 2E depicts the product 100 after one or more CMP processes were performed to remove excess materials (i.e., the bulk copper layer 122 and the conductive adhesion layer 116) positioned above the surface of the layer of insulating material 104 and outside of the trench/vias 102/103. Importantly, due to the prior removal of the portions of the conductive liner layer 120 positioned outside of the smaller first trench/via 102 by performing the above-described wet isotropic etching process, it is not necessary to perform a CMP process to remove any undesired portions of the conductive liner layer 120, thereby avoiding the problems noted in the background section of this application with respect to removing such a conductive liner layer by performing a CMP process. As a result, a first conductive structure 127 was formed in the first trench/via 102 and a second conductive structure 129 was formed in the second trench/via 103. As depicted, the first conductive structure 127 is comprised of the conductive adhesion layer 116 and the conductive liner layer portion 120A. Moreover, since the conductive liner layer 120 was formed so as to substantially fill the remaining portions of the first trench/via 102 above the conductive adhesion layer 116, very little if any of the bulk copper material 122 is present in the first conductive structure 127 (except for perhaps minor amounts of copper that remain due to perhaps incomplete removal of the copper material or filling small recesses in the upper surface of the first conductive structure 127 with copper prior to CMP removal of the bulk copper material 122). In contrast, the second conductive structure 129 is comprised of the conductive adhesion layer 116 and the bulk copper material 122 and it is free of the conductive liner layer 120. Of course, one or both of the first conductive structure 127 or the second conductive structure 129 may comprise additional conductive materials (not shown). For example, a conformal barrier layer may be deposited in both of the trench/vias 102/103 prior to the formation of the conductive adhesion layer 116 that remains in both of the structures 127/129.

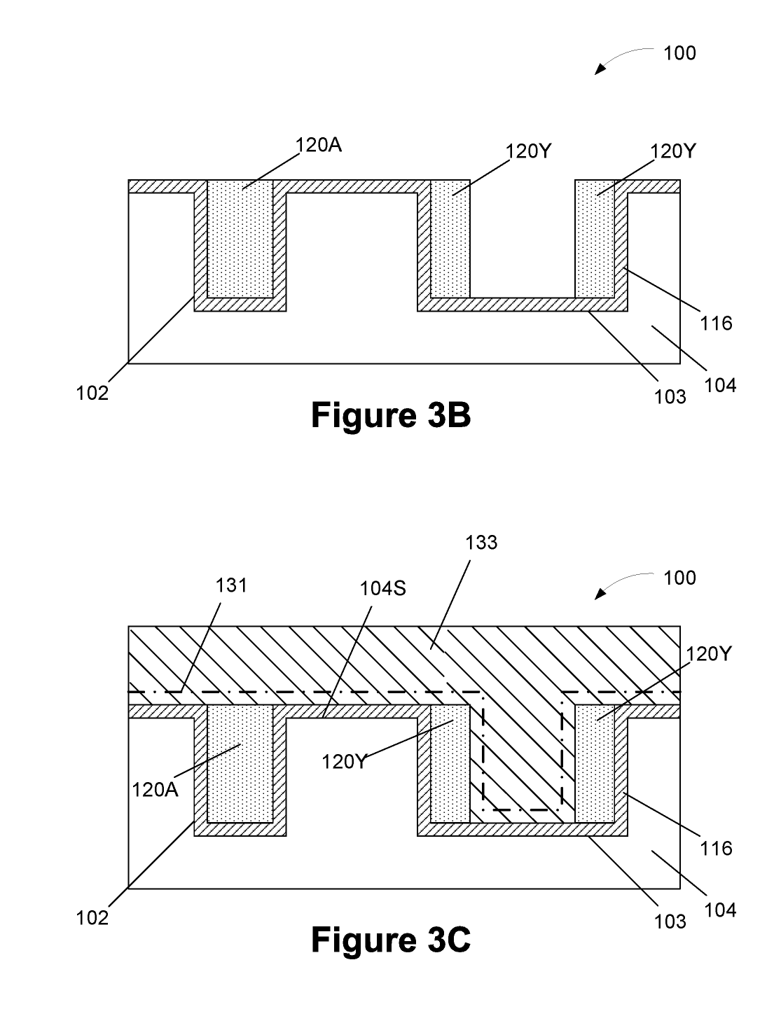

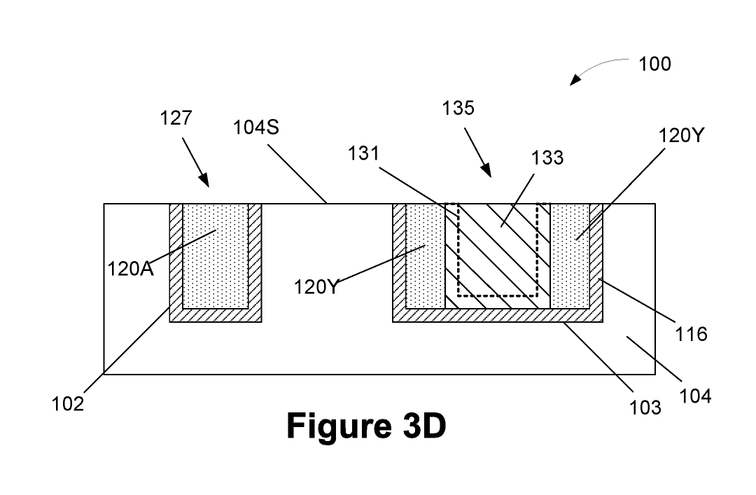

FIGS. 3A-3D depict various other novel methods disclosed herein for forming conductive structures, such as conductive lines/vias. FIG. 3A depicts the product 100 at a point in fabrication that corresponds to that depicted in FIG. 2B, i.e., after the formation of the conductive adhesion layer 116 and the conductive liner layer 120.

FIG. 3B depicts the product 100 after a timed, dry anisotropic etching process was performed to selectively remove the conductive liner layer 120 relative to the conductive adhesion layer 116. Note that the dry anisotropic etching process is performed such that a portion 120A of the conductive liner layer 120 remains in the smaller first trench/via 102. Also note that, due to the anisotropic nature of the etching process, a conductive internal sidewall spacer 120Y comprised of the material of the conductive liner layer 120 is formed in the relatively wider second trench/via 103. In one illustrative embodiment, the conductive internal sidewall spacer 120Y may have a lateral width at its base that corresponds approximately to the as-deposited thickness of the conductive liner layer 120.

FIG. 3C depicts the product 100 after several process operations were performed. In general, one or more conductive materials will be formed above the product 100 to complete the formation of a conductive structure in the second trench/via 103. For example, in one embodiment, a CVD or an ALD process was performed to form a titanium nitride/tungsten nucleation layer 131 (shown as a dashed line) above the conductive liner layer portion 120A, the conductive adhesion layer 116 and above the internal spacer 120Y. Thereafter, a bulk deposition process was performed to form bulk tungsten material 133 across the product 100 such that it overfills the second trench/via 103. The bulk tungsten material 133 may be formed by performing any of a variety of known deposition processes, e.g., a substantially tungsten free CVD tungsten deposition process. Of course, the conductive materials formed on the product 100 at the point of processing depicted in FIG. 3C may vary depending upon the particular application.

FIG. 3D depicts the product 100 after one or more CMP processes were performed to remove excess materials (i.e., the bulk tungsten material 133, the titanium nitride/tungsten nucleation layer 131, the conductive adhesion layer 116 and the conductive liner layer 120) positioned above the surface 104S of the layer of insulating material 104 and outside of the trench/vias 102/103. As a result, the above-described first conductive structure 127 is formed in the first trench/via 102 and a third conductive structure 135 in formed in the second trench/via 103. As depicted, the first conductive structure 127 is comprised of the conductive adhesion layer 116 and the conductive liner layer portion 120A. Moreover, since the conductive liner layer 120 was formed so as to substantially fill the remaining portions of the first trench/via 102 above the conductive adhesion layer 116, very little if any of the bulk tungsten material 133 is present in the first conductive structure 127 (except for perhaps minor amounts of tungsten that remain due to perhaps incomplete removal of the tungsten material or filling small recesses in the upper surface of the first conductive structure 127 with tungsten prior to CMP removal of the bulk tungsten material 133). In contrast, the conductive structure 135 is comprised of the conductive adhesion layer 116, the conductive internal spacer 120Y, the titanium nitride/tungsten nucleation layer 131 and the bulk tungsten material 133. Of course, as noted above, one or both of the first conductive structure 127 or the conductive structure 135 may comprise additional conductive materials (not shown).

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. A method, comprising:
forming a first trench/via and a second trench/via in a layer of insulating material, said first trench/via having a first lateral dimension at an upper surface of said layer of insulating material, said second trench/via having a second lateral dimension at said upper surface of said layer of insulating material, wherein said second lateral dimension is greater than said first lateral dimension;
forming a conductive adhesion layer in said first trench/via and in said second trench/via;
performing a deposition process that results in the formation of a conductive liner layer in said second trench/via and such that a material of said conductive liner layer substantially fills said first trench/via;
performing an etching process to remove at least a portion of said conductive liner layer positioned within said second trench/via and above an upper surface of said conductive adhesion layer while leaving a portion of said conductive liner layer within said first trench/via; and
removing portions of said conductive adhesion layer positioned above an upper surface of said layer of insulating material to define a conductive structure positioned in said first trench/via that comprises a material of said conductive adhesion layer and said material of said conductive liner layer.

2. The method of claim 1, wherein performing said etching process to remove at least a portion of said conductive liner layer comprises performing a wet isotropic etching process.

3. The method of claim 2, wherein performing said wet isotropic etching process removes substantially all of said conductive liner layer from within said second trench/via.

4. The method of claim 1, wherein performing said etching process to remove at least a portion of said conductive liner layer comprises performing a dry anisotropic etching process.

5. The method of claim 4, wherein performing said dry anisotropic etching process results in the formation of an internal sidewall spacer within said second trench/via that is comprised of said material of said conductive liner layer.

6. The method of claim 1, wherein said conductive liner layer comprises a noble metal.

7. The method of claim 1, wherein said conductive liner layer comprises ruthenium.

8. The method of claim 7, wherein said conductive liner layer has a thickness that falls within a range of 5-40 nm.

9. The method of claim 1, wherein said second lateral dimension is at least 10 nm greater than said first lateral dimension.

10. The method of claim 1, wherein said conductive adhesion layer comprises titanium nitride.

11. A method, comprising:
forming a first trench/via and a second trench/via in a of layer insulating material, said first trench/via having a first lateral dimension at an upper surface of said layer of insulating material, said second trench/via having a second lateral dimension at said upper surface of said layer of insulating material, wherein said second lateral dimension is greater than said first lateral dimension;
forming a conductive adhesion layer in said first trench/via and in said second trench/via and above said upper surface of said layer of insulating material;
performing a deposition process that results in the formation of a conductive liner layer in said second trench/via and such that a material of said conductive liner layer substantially fills said first trench/via;
performing a wet isotropic etching process to remove substantially all of said conductive liner layer positioned within said second trench/via and from above said upper surface of said layer of insulating material while leaving a portion of said conductive liner layer within said first trench/via;
overfilling at least said second trench/via with a bulk conductive material; and
performing at least one process operation to remove portions of said bulk conductive material and said conductive adhesion layer from above said upper surface of said layer of insulating material to thereby result in the formation of a first conductive structure in said first trench/via and a second conductive structure in said second trench/via.

12. The method of claim 11, wherein said bulk conductive material comprises one of copper or tungsten.

13. The method of claim 11, wherein said conductive liner layer comprises ruthenium.

14. The method of claim 11, wherein said second lateral dimension is at least 10 nm greater than said first lateral dimension.

15. The method of claim 11, wherein said first conductive structure is substantially free of said bulk conductive material.

16. A method, comprising:
forming a first trench/via and a second trench/via in a layer of insulating material, said first trench/via having a first lateral dimension at an upper surface of said layer of insulating material, said second trench/via having a second lateral dimension at said upper surface of said layer of insulating material, wherein said second lateral dimension is greater than said first lateral dimension;
forming a conductive adhesion layer in said first trench/via and in said second trench/via and above said upper surface of said layer of insulating material;
performing a deposition process that results in the formation of a conductive liner layer in said second trench/via and such that a material of said conductive liner layer substantially fills said first trench/via;
performing a dry anisotropic etching process on said conductive liner layer such that, after said dry anisotropic etching process is completed, a portion of said material of said conductive liner layer substantially fills said first trench/via and an internal sidewall spacer is defined within said second trench/via that is comprised of said material of said conductive liner layer;
overfilling at least said second trench/via with a bulk conductive material; and
performing at least one process operation to remove portions of said bulk conductive material, said conductive adhesion layer and said conductive liner layer from above said upper surface of said layer of insulating material to thereby result in the formation of a first conductive structure in said first trench/via and a second conductive structure in said second trench/via.

17. The method of claim 16, wherein said conductive liner layer comprises a noble metal.

18. The method of claim 16, wherein said conductive liner layer comprises ruthenium.

19. The method of claim 16, wherein said first conductive structure is substantially free of said bulk conductive material.

20. The method of claim 16, wherein said second lateral dimension is at least 10 nm greater than said first lateral dimension.
